(19) United States
(12) Patent Application Publication
(10) Pub. No.: US 2026/0245637 A1
(43) Pub. Date: Aug. 20, 2026

(54) NEGATIVE VOLTAGE DISCHARGE CIRCUIT

(71) Applicant: Shanghai Huahong Grace Semiconductor Manufacturing Corporation, Shanghai (CN)

(72) Inventor: Guangjun YANG, Shanghai (CN)

(21) Appl. No.: 19/471,237

(22) PCT Filed: May 21, 2024
(86) PCT No.: PCT/CN2024/094377

§ 371 Date: Sep. 30, 2025

(30) Foreign Application Priority Data
May 31, 2023 (CN) 202310634521.1

(51) Int. Cl. G11C 16/30; G11C 5/14

(52) U.S. Cl. CPC G11C 16/30; G11C 5/147

(57) ABSTRACT

The present application discloses a negative voltage discharge circuit including a fractional discharge module and a clamp discharge path. The fractional discharge module fractionally controls a discharge current in a discharge process, such that a voltage of a first signal wire is gradually increased from an initial negative voltage to a first voltage less than a target voltage. A first and a second switch of the clamp discharge path are connected to form a discharge path. The clamp discharge path to be switched on after the voltage of the first signal wire is increased to the first voltage. A gate and a drain of the first NMOS transistor are both connected to a second end of the first switch, and a source is connected to a second signal wire. The first voltage is set to be less than a positive switch-on voltage of a PN junction of the first NMOS transistor.

### TECHNICAL FIELD

The present application relates to a semiconductor integrated circuit, and in particular, to a negative voltage discharge circuit.

### BACKGROUND

A memory such as a flash includes a variety of operations, such as program, erase and read. During the operations of the memory, it is necessary to employ a positive electric voltage greater than a power supply voltage or a negative electric voltage (that is, a negative voltage) below 0V. The positive electric voltage is referred to as a positive voltage, and the negative electric voltage is referred to as the negative voltage. Both the positive voltage and the negative voltage need to be supported from a charge pump.

FIG. 1 is a schematic diagram showing a structure of an existing flash employing both a positive voltage and a negative voltage. A positive voltage charge pump 102 provides a positive voltage VEP to a memory array 101 of the flash, and a negative voltage charge pump 103 provides a negative voltage VNEG to the memory array 101 of the flash.

The positive voltage VEP or the negative voltage VNEG is only supplied when being employed as required during the operations. When the operations are completed, a signal wire corresponding to the positive voltage VEP needs to be discharged to a target voltage such as 0V, and a signal wire corresponding to the negative voltage VNEG needs to be discharged to a target voltage such as 0V. Discharges of the positive voltage VEP and the negative voltage VNEG are achieved by a positive voltage discharge circuit and a negative voltage discharge circuit, respectively.

FIG. 2A shows a diagram of an existing positive voltage discharge circuit. The positive voltage discharge circuit 104 includes discharge paths 105 and 106, wherein a discharge current of the discharge path 105 is controlled by a current source 109a, a control end of the current source 109a is connected to a control signal RMPDN, and the control signal RMPDN is generated after the operations of the flash are finished. In this way, the discharge path 105 is switched on from the start of the discharge, thereby forming a discharge current and initiating the discharge.

Diode-connected NMOS transistors N102c and N102d are connected between a first end of the current source 109a and the signal wire corresponding to the positive voltage VEP. A second end of the current source 109a is grounded.

The discharge path 106 includes a switch formed by an NMOS transistor N101, a source of the NMOS transistor N101 is grounded, a gate of the NMOS transistor N101 is connected to a control signal HVlow, and diode-connected NMOS transistors N102a and N102b are connected between a drain of the NMOS transistor N101 and the signal wire corresponding to the negative voltage VNEG.

Discharge processes of the control signal HVlow and the signal wire corresponding to the positive voltage VEP are correlated. When a voltage of the signal wire corresponding to the positive voltage VEP is discharged from the positive voltage VEP to a set voltage, the control signal HVlow becomes valid and enables the discharge path 106 to be switched on, thereby initiating the discharge through the discharge path 106.

Therefore, it is necessary to obtain the control signal HVlow by sampling and comparing the voltage of the signal wire corresponding to the positive voltage VEP. In FIG. 2, a sample circuit 107 is formed by a resistor string, and an output end of the resistor string outputs a voltage division of the voltage of the signal wire of the positive voltage VEP. A compare circuit is formed by a comparator 108. A partial voltage output from the resistor string is input to a normal input end of the comparator 108, an inverted input end of the comparator 108 is connected to a reference voltage, and an output end of the comparator 108 outputs the control signal HVlow.

FIG. 3A shows waveform plots of control signals RMPDN and HVlow.

FIG. 3B shows a waveform curve of a positive voltage VEP, that is, a voltage waveform curve of a signal wire corresponding to the positive voltage VEP. A voltage of the signal wire corresponding to the positive voltage VEP is 0V before the operations, is increased to the positive voltage VEP during the operations, and then is decreased from the positive voltage VEP. A process of decreasing the voltage of the signal wire from the positive voltage VEP is a discharge process. The discharge process includes a first decrease stage controlled by the control signal RMPDN and a second decrease stage controlled by the control signal HVlow. The two decrease stages are separated by a dotted line. It can be seen that discharge rates of the two decrease stages are different.

FIG. 2B shows a diagram of an existing negative voltage discharge circuit. The negative voltage discharge circuit 110 includes discharge paths 111 and 112, wherein a discharge current of the discharge path 111 is controlled by a current source 109b, and a control end of the current source 109b is connected to the control signal RMPDN. Since control signals of the discharge path 111 and the discharge path 105 of the existing positive pressure discharge circuit 104 in FIG. 2A are both signals RMPDN, the discharge path 111 is switched on from the start of the discharge.

Diode-connected NMOS transistors N102e and N102f are connected between a first end of the current source 109b and a signal wire corresponding to a negative voltage VNEG.

A second end of the current source 109b is grounded.

The discharge path 112 includes a switch transistor consisting of an NMOS transistor N105, and a gate of the NMOS transistor N105 is connected to a control signal HVlow. A source of the NMOS transistor N105 is connected to the signal wire corresponding to the negative voltage VNEG, and a drain of the NMOS transistor N105 and a drain of the NMOS transistor N104 are connected to a gate and a drain of the NMOS transistor N103.

The gate of the NMOS transistor N104 is connected to a fixed bias voltage such as 0V or VDD, which is represented by 0/VDD in FIG. 2B, and the source of the NMOS transistor N104 is grounded. A channel of the NMOS transistor N104 will remain in a switch-on state. After the control signal HVlow enables the NMOS transistor N105 to be switched on, the signal wire corresponding to the negative voltage VNEG is discharged through the NMOS transistors N105 and N104.

A source of the NMOS transistor N103 is grounded. When the overshoot is generated during the discharge, the voltage of the signal wire corresponding to the negative voltage VNEG is greater than 0V. Because the gate and the drain of the NMOS transistor N103 are connected to the signal wire corresponding to the negative voltage VNEG, voltages of the gate and the drain of the NMOS transistor N103 are increased. In this way, the NMOS transistor N103 is switched on, thereby decreasing the voltage of the signal wire corresponding to the negative voltage VNEG, and consequently decreasing an overshoot voltage.

In the prior art, the two control signals (that is, the control signals RMPDN and HVlow) of the existing negative voltage discharge circuit shown in FIG. 2B are identical to the two control signals of the existing positive voltage discharge circuit shown in FIG. 2A. In this way, the discharge process of the existing negative voltage discharge circuit includes two stages as well. FIG. 3B shows a waveform curve of a negative voltage VNEG, that is, a voltage waveform curve of a signal wire corresponding to the negative voltage VNEG. A voltage of the signal wire corresponding to the negative voltage VNEG is 0V before the operations, is decreased to the negative voltage VNEG during the operations, and then is increased from the negative voltage VNEG. The process of increasing the voltage of the signal wire corresponding to the negative voltage VNEG from the negative voltage VNEG is the discharge process. The discharge process includes a first increase stage controlled by the control signal RMPDN and a second increase stage controlled by the control signal HVlow.

A discharge path 111 is switched on in the first increase stage.

A discharge path 112 is switched on in the second increase stage. If no overshoot is generated, An NMOS transistor N103 is not switched on. However, the voltage of the signal wire corresponding to the negative voltage VNEG is substantially a negative voltage in the second increase stage. In this way, it is easy to make a PN junction between an N+doped drain region of the NMOS transistor N103 and a P-type doped substrate be positively switched on, and generate a latch-up effect.

### BRIEF SUMMARY

According to some embodiments in this application, a negative voltage discharge circuit disclosed in this application comprising: a fractional discharge module and a clamp discharge path.

The fractional discharge module is connected between a first signal wire and a second signal wire.

A voltage of the first signal wire is an initial negative voltage before the discharge.

The second signal wire has a target voltage greater than the initial negative voltage.

The fractional discharge module forms a discharge current between the first signal wire and the second signal wire in a discharge process, and the discharge current is fractionally controlled and enables the voltage of the first signal wire to be gradually increased from the initial negative voltage to a first voltage less than the target voltage.

The clamp discharge path is configured to continuously discharge the voltage of the first signal wire to the target voltage after the voltage of the first signal wire reaches the first voltage, and prevent the voltage of the first signal wire from generating the overshoot.

The clamp discharge path includes a first switch, a second switch and a first NMOS transistor.

A first end of the first switch is connected to the first signal wire, a second end of the first switch is connected to a first end of the second switch, and a second end of the second switch is connected to the second signal wire.

A control end of the first switch is connected to a first control signal, and the first control signal controls the switch on or off of the clamp discharge path and enables the clamp discharge path to be switched on after the voltage of the first signal wire is increased to the first voltage.

A control end of the second switch is connected to a first bias voltage, and the first bias voltage enables the second switch to be turned on.

A gate and a drain of the first NMOS transistor are both connected to the second end of the first switch, and a source of the first NMOS transistor is connected to the second signal wire; and a PN junction is provided between a drain region of the first NMOS transistor and a P-type substrate.

In a process of initiating the discharge process by the clamp discharge path, when the voltage of the first signal wire generates the overshoot, the first NMOS transistor is switched on, such that the voltage of the first signal wire returns to the target voltage; and the first voltage is set to be less than a positive switch on voltage of the PN junction, so as to prevent the PN junction from being positively switched on and thus prevent the first NMOS transistor from generating a latch-up effect.

In some cases, the fractional discharge module includes a plurality of discharge paths.

Each of the discharge paths of the fractional discharge module is fractionally switched on according to a magnitude of the voltage of the first signal wire in the discharge process, such that the discharge current is fractionally controlled.

In some cases, each of the discharge paths of the fractional discharge module includes a current source, a second end of the current source of each of the discharge paths is connected to the second signal wire and a plurality of diode-connected MOS transistors are connected in series between a first end of the current source and the first signal wire, and the number of the MOS transistors of the discharge path switched on in the previous step is greater than that of the MOS transistors switched on in the later step.

In some cases, a first end of a current source of the discharge path switched on in the last step is directly connected to the first signal wire.

In some cases, the initial negative voltage is an operate voltage of a flash.

In some cases, the initial negative voltage is an erase voltage added to a control gate line of the flash during an erase operation, and the first signal wire is the control gate line.

In some cases, the target voltage is 0V, and the second signal wire is a ground wire.

In some cases, the fractional discharge module includes three discharge paths.

A current source of a first discharge path is a first current source, and two of the MOS transistors are connected in series between a first end of the first current source and the first signal wire.

A current source of a second discharge path is a second current source, and one of the MOS transistors is connected in series between a first end of the second current source and the first signal wire.

A current source of a third discharge path is a third current source, and a first end of the third current source is connected to the first signal wire.

A control end of the first current source is connected to a second control signal, a control end of the second current source is connected to a third control signal, and a control end of the third current source is connected to a fourth control signal.

The first discharge path, the second discharge path and the third discharge path are fractionally switched on according to a chronological order.

In some cases, discharge rates of the first discharge path, the second discharge path and the third discharge path are decreased sequentially according to the chronological order.

In some cases, the negative voltage discharge circuit further includes a signal generation circuit forming the third control signal and the fourth control signal.

In some cases, the signal generation circuit includes a sample circuit and a compare circuit.

The sample circuit is configured to sample a voltage of the first signal wire and form a sample voltage.

The compare circuit is configured to compare the sample voltage and a selected reference voltage, and form the third control signal and the fourth control signal according to a comparison result.

When the voltage of the first signal wire is greater than or equal to a second voltage and less than a third voltage, the third control signal becomes valid and enables the second current source to be switched on.

When the voltage of the first signal wire is greater than or equal to the third voltage and less than the first voltage, the fourth control signal becomes valid and enables the third current source to be switched on.

In some cases, the second control signal becomes valid from the start of discharge until the voltage of the first signal wire is increased to the second voltage.

In some cases, the sample circuit consists of a resistor string connected between the first signal wire and the ground wire, and an output end is formed at a resistor joint of the resistor string and outputs the sample voltage.

In some cases, the compare circuit includes a first comparator and a second comparator, and the first comparator has a first input end connected to the sample voltage, a second input end connected to a first reference voltage and an output end outputting the third control signal.

The second comparator has a first input end connected to the sample voltage, a second input end connected to a second reference voltage and an output end outputting the fourth control signal.

In some cases, a valid level of the third control signal is a high level, the first input end of the first comparator is a normal input end, and the second input end of the first comparator is an inverted input end.

A valid level of the fourth control signal is a high level, the first input end of the second comparator is a normal input end, and the second input end of the second comparator is an inverted input end.

In some cases, the MOS transistor disposed in each of the discharge paths employs an NMOS transistor.

In some cases, the first switch employs an NMOS transistor.

The second switch employs an NMOS transistor, and the first bias voltage is 0V or a power supply voltage.

The first NMOS transistor employs a native NMOS transistor, and a threshold voltage of the native NMOS transistor is close to 0V.

In the present application, the fractional discharge module is disposed in the negative voltage discharge circuit. The fractional discharge module can gradually increase the initial negative voltage of the first signal wire to the first voltage close to the target voltage. Then, the discharge is initiated by the clamp discharge path. Because the first NMOS transistor preventing the overshoot from being generated is provided in the clamp discharge path, if the first voltage is too low, it is easy to make the PN junction formed between the drain region of the first NMOS transistor and the P-type substrate be positively switched on, and thus generate the latch-up effect. However, the present application can control the first voltage very well through the fractional discharge module, thereby preventing the PN junction of the first NMOS from being positively switched on, and preventing the latch-up effect from being generated.

### BRIEF DESCRIPTION OF THE DRAWINGS

The present application will be described in further detail below in conjunction with the figures and the detailed description:

FIG. 1 is a schematic diagram showing a structure of an existing flash employing both a positive voltage and a negative voltage;

FIG. 2A is a diagram of an existing positive voltage discharge circuit;

FIG. 2B is a diagram of an existing negative voltage discharge circuit;

FIG. 3A is waveform plots of control signals in FIG. 2A and FIG. 2B;

FIG. 3B is waveform plots of a positive voltage in FIG. 2A and a negative voltage in FIG. 2B;

FIG. 4 is a diagram of a negative voltage discharge circuit according to an embodiment of the present application; and

FIG. 5 is a waveform plot of a negative voltage of a negative voltage discharge circuit according to an embodiment of the present application.

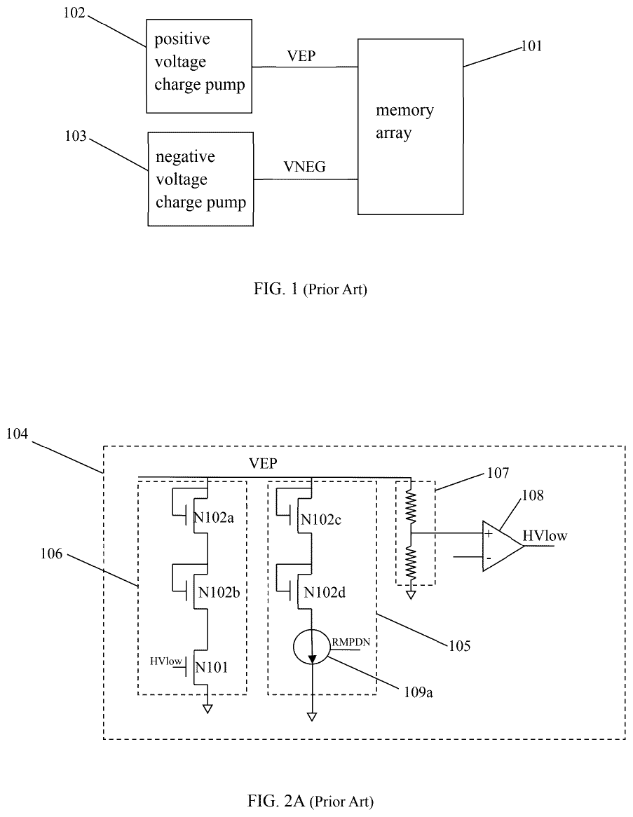

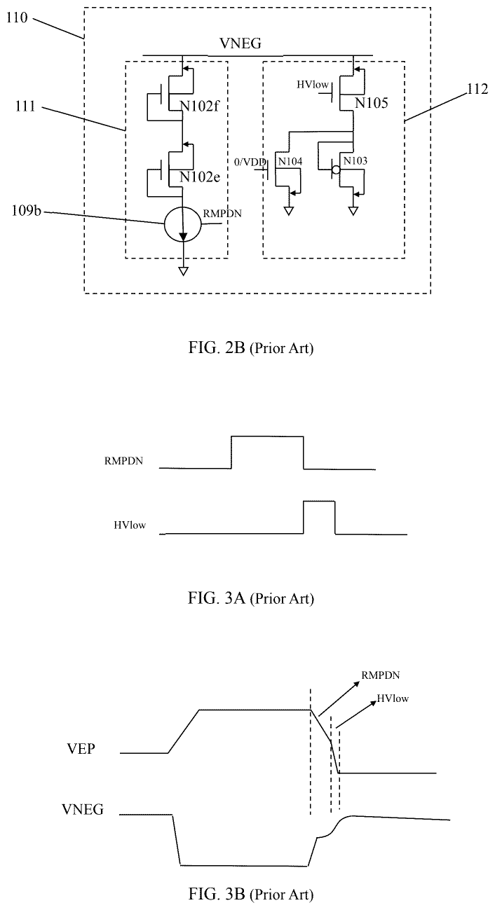

### DETAILED DESCRIPTION OF THE DISCLOSURE

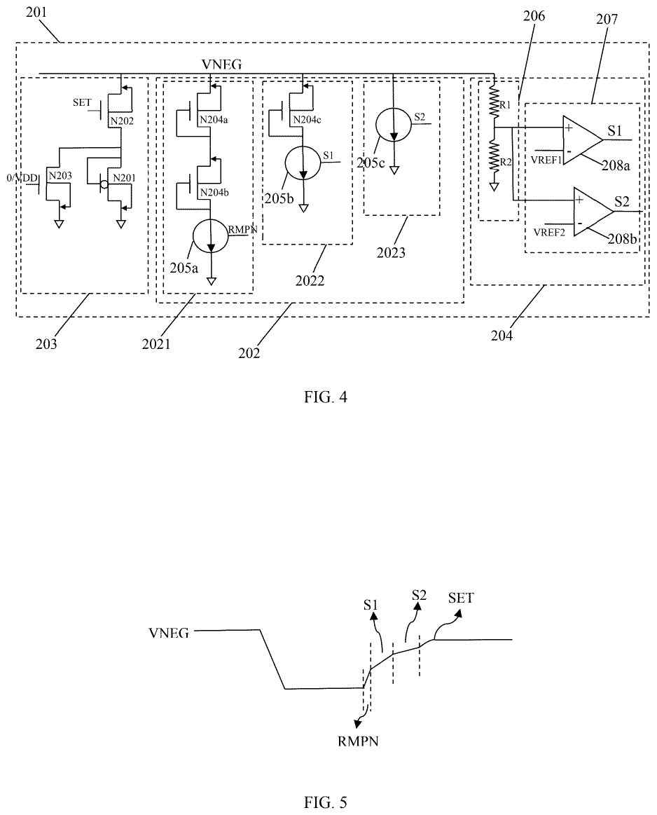

FIG. 4 is a diagram of a negative voltage discharge circuit according to an embodiment of the present application. The negative voltage discharge circuit 201 of the embodiment of the present application includes a fractional discharge module 202 and a clamp discharge path 203.

The fractional discharge module 202 is connected between a first signal wire and a second signal wire.

A voltage of the first signal wire is an initial negative voltage VNEG before the discharge. FIG. 4 shows the initial negative voltage VNEG, and the first signal wire is a signal wire corresponding to the initial negative voltage VNEG.

The second signal wire has a target voltage greater than the initial negative voltage VNEG.

In some embodiments, the initial negative voltage VNEG is an operate voltage of the flash. The initial negative voltage VNEG is an erase voltage added to a control gate line of the flash during an erase operation, and the first signal wire is the control gate line. The target voltage is 0V, and the second signal wire is a ground wire.

The fractional discharge module 202 forms a discharge current between the first signal wire and the second signal wire in a discharge process, the discharge current is fractionally controlled and a voltage of the first signal wire is gradually increased from the initial negative voltage VNEG to a first voltage less than the target voltage.

The clamp discharge path 203 is configured to continuously discharge a voltage of the first signal wire to the target voltage after the voltage of the first signal wire reaches the first voltage, and prevent the voltage of the first signal wire from generating the overshoot.

The clamp discharge path 203 includes a first switch N202, a second switch N203 and a first NMOS transistor N201.

A first end of the first switch N202 is connected to the first signal wire, a second end of the first switch N202 is connected to a first end of the second switch N203, and a second end of the second switch N203 is connected to the second signal wire.

A control end of the first switch N202 is connected to a first control signal SET, the first control signal SET controls the switch on or off of the clamp discharge path 203, and the clamp discharge path 203 is switched on after the first signal wire is increased to the first voltage.

A control end of the second switch N203 is connected to a first bias voltage, and the first bias voltage enables the second switch N203 to be turned on.

A gate and a drain of the first NMOS transistor N201 are both connected to a second end of the first switch N202, and a source of the first NMOS transistor N201 is connected to the second signal wire; and a PN junction is provided between a drain region of the first NMOS transistor N201 and a P-type substrate.

In a process of initiating the discharge process by the clamp discharge path 203, when the voltage of the first signal wire generates the overshoot, the first NMOS transistor N201 is switched on, such that the voltage of the first signal wire returns to the target voltage; and the first voltage is set to be less than a positive switch-on voltage of the PN junction, so as to prevent the PN junction from being positively switched on and thus prevent the first NMOS transistor N201 from generating a latch-up effect.

In some embodiments, the first switch N202 employs an NMOS transistor.

The second switch N203 employs an NMOS transistor, and the first bias voltage is 0V or a power supply voltage represented by 0/VDD in FIG. 4.

The first NMOS transistor N201 employs a native NMOS transistor.

In an embodiment of the present application, the fractional discharge module 202 includes a plurality of discharge paths.

Each of the discharge paths of the fractional discharge module 202 is fractionally switched on according to a magnitude of the voltage of the first signal wire in the discharge process, such that the discharge current is fractionally controlled.

Each of the discharge paths of the fractional discharge module 202 includes a current source, a second end of the current source of each of the discharge paths is connected to the second signal wire and -connected MOS transistors are connected in series between a first end of the current source and the first signal wire, and the number of the MOS transistors of the discharge path switched on in the previous step is greater than that of the MOS transistors switched on in the later step.

The MOS transistor disposed in each of the discharge paths employs an NMOS transistor.

A first end of a current source of the discharge path switched on in the last step is directly connected to the first signal wire.

In some embodiments, the fractional discharge module 202 includes three discharge paths.

A current source of a first discharge path 2021 is a first current source 205a, two of the MOS transistors are connected in series between a first end of the first current source 205a and the first signal wire, and two of the MOS transistors are NMOS transistors N204a and N204b.

A current source of a second discharge path 2022 is a second current source 205b, and one of the MOS transistors (that is, an NMOS transistor N204c) is connected in series between a first end of the second current source 205b and the first signal wire.

A current source of a third discharge path 2023 is a third current source, and a first end of the third current source is connected to the first signal wire. The third current source is a current source of the discharge path switched on in the last step.

A control end of the first current source 205a is connected to a second control signal RMPN, a control end of the second current source 205b is connected to a third control signal S1, and a control end of the third current source is connected to a fourth control signal S2.

The first discharge path 2021, the second discharge path 2022 and the third discharge path 2023 are fractionally switched on according to a chronological order.

Discharge rates of the first discharge path 2021, the second discharge path 2022 and the third discharge path 2023 are decreased sequentially according to the chronological order.

The negative voltage discharge circuit 201 further includes a signal generation circuit forming the third control signal S1 and the fourth control signal S2.

In some embodiments, the signal generation circuit includes a sample circuit 206 and a compare circuit 207.

The sample circuit 206 is configured to sample a voltage of the first signal wire and form a sample voltage.

In some preferred embodiments, the sample circuit 206 consists of a resistor string connected between the first signal wire and a ground wire. In FIG. 4, the resistor string is formed by connecting resistors R1 and R2 in series. An output end is formed at a resistor joint of the resistor string and outputs the sample voltage.

The compare circuit 207 is configured to compare the sample voltage with a selected reference voltage, and form the third control signal S1 and the fourth control signal S2 according to a comparison result.

When the voltage of the first signal wire is greater than or equal to a second voltage and less than a third voltage, the third control signal S1 becomes valid and enables the second current source 205b to be switched on.

When the voltage of the first signal wire is greater than or equal to the third voltage and less than the first voltage, the fourth control signal S2 becomes valid and enables the third current source to be switched on.

The second control signal RMPN becomes valid from the start of discharge until the voltage of the first signal wire is increased to the second voltage.

In some preferred embodiments, the compare circuit 207 includes a first comparator 208a and a second comparator 208b. The first comparator 208a has a first input end connected to the sample voltage, a second input end connected to a first reference voltage VREF1 and an output end outputting the third control signal S1;

The second comparator 208b has a first input end connected to the sample voltage, a second input end connected to a second reference voltage VREF2 and an output end outputting the fourth control signal S2.

A valid level of the third control signal S1 is a high level, the first input end of the first comparator 208a is a normal input end, and the second input end of the first comparator 208a is an inverted input end.

A valid level of the fourth control signal S2 is a high level, the first input end of the second comparator 208b is a normal input end and the second input end of the second comparator 208b is an inverted input end.

FIG. 5 is a waveform plot of a negative voltage of a negative voltage discharge circuit according to an embodiment of the present application, that is, a voltage waveform plot of a first signal wire. A voltage of the first signal wire is 0V before the operations of a flash, and is decreased to the negative voltage VNEG during the operations of the flash. After the operations are completed, the discharge is initiated, and then the voltage of the first signal wire is gradually increased to 0V from the negative voltage VNEG. In the discharge process, the negative voltage VNEG maintained before the discharge is the initial negative voltage. After the discharge is initiated, the negative voltage is gradually increased from the initial negative voltage VNEG. FIG. 5 shows four stages of increasing a voltage of the first signal wire. A first increase stage is controlled by a second control signal RMPN, a second increase stage is controlled by a third control signal S1, a third increase stage is controlled by a fourth control signal S2, and a fourth increase stage is controlled by a first control signal SET. Because the signals S1 and S2 are obtained after the voltage of the first signal wire is sampled, the voltage of the first signal wire has reached a relatively large value in the fourth increase stage, which can prevent the defect that the clamp transistor (that is, corresponding to the PN junction between the drain region of the first NMOS transistor N201 and the substrate in the embodiment of the present application) is easily positively switched on when the last increase stage is controlled by the HVlow in the prior art in FIG. 3B, and thus prevent a latch-up effect from being generated.

In the embodiment of the present application, the fractional discharge module 202 is disposed in the negative voltage discharge circuit 201. The fractional discharge module 202 can gradually increase the initial negative voltage VNEG of the first signal wire to the first voltage close to the target voltage. Then, the discharge is initiated by the clamp discharge path 203. Because the first NMOS transistor N201 preventing the overshoot from being generated is provided in the clamp discharge path 203, if the first voltage is too low, it is easy to make the PN junction formed between the drain region of the first NMOS transistor N201 and the P-type substrate be positively switched on, and thus generate the latch-up effect. However, the embodiment of the present application can control the first voltage well through the fractional discharge module 202, thereby preventing the PN junction of the first NMOS transistor N201 from being positively switched on, and preventing the latch-up effect from being generated.

The present application is described in detail above by means of specific embodiments, but these do not constitute limitations on the present application. Those skilled in the art may make many variations and improvements without departing from the principles of the present application, which should be regarded as falling within the scope of protection of the present application.

What is claimed is:

1. A negative voltage discharge circuit, comprising a fractional discharge module and a clamp discharge path,
the fractional discharge module is connected between a first signal wire and a second signal wire;
a voltage of the first signal wire is an initial negative voltage before the discharge;
the second signal wire has a target voltage greater than the initial negative voltage;
the fractional discharge module forms a discharge current between the first signal wire and the second signal wire in a discharge process, and the discharge current is fractionally controlled and enables the voltage of the first signal wire to be gradually increased from the initial negative voltage to a first voltage less than the target voltage;
the clamp discharge path is configured to continuously discharge the voltage of the first signal wire to the target voltage after the voltage of the first signal wire reaches the first voltage, and prevent the voltage of the first signal wire from generating the overshoot;
the clamp discharge path comprises a first switch, a second switch and a first NMOS transistor;
a first end of the first switch is connected to the first signal wire, a second end of the first switch is connected to a first end of the second switch, and a second end of the second switch is connected to the second signal wire;
a control end of the first switch is connected to a first control signal, and the first control signal controls the switch on or off of the clamp discharge path and enables the clamp discharge path to be switched on after the voltage of the first signal wire is increased to the first voltage;
a control end of the second switch is connected to a first bias voltage, and the first bias voltage enables the second switch to be turned on;
a gate and a drain of the first NMOS transistor are both connected to the second end of the first switch, and a source of the first NMOS transistor is connected to the second signal wire;
and a PN junction is provided between a drain region of the first NMOS transistor and a P-type substrate; and
in a process of initiating the discharge process by the clamp discharge path, when the voltage of the first signal wire generates the overshoot, the first NMOS transistor is switched on, such that the voltage of the first signal wire returns to the target voltage; and the first voltage is set to be less than a positive switch on voltage of the PN junction, so as to prevent the PN junction from being positively switched on and thus prevent the first NMOS transistor from generating a latch-up effect.

2. The negative voltage discharge circuit according to claim 1, wherein the fractional discharge module comprises a plurality of discharge paths; and
each of the discharge paths of the fractional discharge module is fractionally switched on according to a magnitude of the voltage of the first signal wire in the discharge process, such that the discharge current is fractionally controlled.

3. The negative voltage discharge circuit according to claim 2, wherein each of the discharge paths of the fractional discharge module comprises a current source, a second end of the current source of each of the discharge paths is connected to the second signal wire and a plurality of diode-connected MOS transistors are connected in series between a first end of the current source and the first signal wire, and the number of the MOS transistors of the discharge path switched on in the previous step is greater than that of the MOS transistors switched on in the later step.

4. The negative voltage discharge circuit according to claim 3, wherein a first end of a current source of the discharge path switched on in the last step is directly connected to the first signal wire.

5. The negative voltage discharge circuit according to claim 4, wherein the initial negative voltage is an operate voltage of a flash.

6. The negative voltage discharge circuit according to claim 5, wherein the initial negative voltage is an erase voltage added to a control gate line of the flash during an erase operation, and the first signal wire is the control gate line.

7. The negative voltage discharge circuit according to claim 6, wherein the target voltage is 0V, and the second signal wire is a ground wire.

8. The negative voltage discharge circuit according to claim 7, wherein the fractional discharge module comprises three discharge paths;
a current source of a first discharge path is a first current source, and two of the MOS transistors are connected in series between a first end of the first current source and the first signal wire;
a current source of a second discharge path is a second current source, and one of the MOS transistors is connected in series between a first end of the second current source and the first signal wire;
a current source of a third discharge path is a third current source, and a first end of the third current source is connected to the first signal wire;
a control end of the first current source is connected to a second control signal, a control end of the second current source is connected to a third control signal, and a control end of the third current source is connected to a fourth control signal; and
the first discharge path, the second discharge path and the third discharge path are fractionally switched on according to a chronological order.

9. The negative voltage discharge circuit according to claim 7, wherein discharge rates of the first discharge path, the second discharge path and the third discharge path are decreased sequentially according to the chronological order.

10. The negative voltage discharge circuit according to claim 7, further comprising a signal generation circuit forming the third control signal and the fourth control signal.

11. The negative voltage discharge circuit according to claim 7, wherein the signal generation circuit comprises a sample circuit and a compare circuit;
the sample circuit is configured to sample a voltage of the first signal wire and form a sample voltage;
the compare circuit is configured to compare the sample voltage and a selected reference voltage, and form the third control signal and the fourth control signal according to a comparison result;
when the voltage of the first signal wire is greater than or equal to a second voltage and less than a third voltage, the third control signal becomes valid and enables the second current source to be switched on; and
when the voltage of the first signal wire is greater than or equal to the third voltage and less than the first voltage, the fourth control signal becomes valid and enables the third current source to be switched on.

12. The negative voltage discharge circuit according to claim 10, wherein the second control signal becomes valid from the start of discharge until the voltage of the first signal wire is increased to the second voltage.

13. The negative voltage discharge circuit according to claim 10, wherein the sample circuit consists of a resistor string connected between the first signal wire and the ground wire, and an output end is formed at a resistor joint of the resistor string and outputs the sample voltage.

14. The negative voltage discharge circuit according to claim 12, wherein the compare circuit comprises a first comparator and a second comparator, and the first comparator has a first input end connected to the sample voltage, a second input end connected to a first reference voltage and an output end outputting the third control signal; and
the second comparator has a first input end connected to the sample voltage, a second input end connected to a second reference voltage and an output end outputting the fourth control signal.

15. The negative voltage discharge circuit according to claim 12, wherein a valid level of the third control signal is a high level, the first input end of the first comparator is a normal input end, and the second input end of the first comparator is an inverted input end; and
a valid level of the fourth control signal is a high level, the first input end of the second comparator is a normal input end, and the second input end of the second comparator is an inverted input end.

16. The negative voltage discharge circuit according to claim 3 or 8, wherein the MOS transistor disposed in each of the discharge paths employs an NMOS transistor.

17. The negative voltage discharge circuit according to claim 1, wherein the first switch employs an NMOS transistor;
the second switch employs an NMOS transistor, and the first bias voltage is 0V or a power supply voltage; and
the first NMOS transistor employs a native NMOS transistor.
